(19) United States
(12) Patent Application Publication
(10) Pub. No.: US 2025/0107288 A1
(43) Pub. Date: Mar. 27, 2025

(54) OPTOELECTRONIC COMPONENT AND METHOD FOR PRODUCING AN OPTOELECTRONIC COMPONENT

(71) Applicant: ams-OSRAM International GmbH, Regensburg (DE)

(72) Inventors: Ion STOLL, Tegernheim (DE); Britta GOEOETZ, Regensburg (DE); Martin STRASSBURG, Donaustauf (DE)

(21) Appl. No.: 18/714,576

(22) PCT Filed: Dec. 7, 2022
(86) PCT No.: PCT/EP2022/084876

§ 371 Date: May 30, 2024

(30) Foreign Application Priority Data
Dec. 9, 2021 (DE) 10 2021 132 512.9

(51) Int. Cl. H01L 33/50; B82Y 20/00; C09B 3/60; C09K 11/02; C09K 11/06; H01L 33/60

(52) U.S. Cl. CPC H01L 33/501; C09B 3/60; C09K 11/02; C09K 11/06; H01L 33/60; B82Y 20/00; C09K 2211/1018; H01L 2933/0041

(57) ABSTRACT

An optoelectronic component includes a semiconductor chip which during operation emits electromagnetic primary radiation of a first wavelength range, and at least one conversion element. The conversion element is designed to emit electromagnetic secondary radiation of a second wavelength range. The electromagnetic secondary radiation is in the infrared spectral range. The conversion element includes at least one wavelength-converting material and a matrix material. The wavelength-converting material is a rylene dye.

### RELATED APPLICATION(S)

This application is a US National Stage Application of International Application PCT/EP2022/084876, filed on 7 Dec. 2022, and claims priority under 35 U.S.C. § 119(a) and 35 U.S.C. § 365(b) from German Patent Application DE 10 2021 132 512.9, filed on 9 Dec. 2021, the contents of which are incorporated herein by reference in their entirety.

### FIELD

The present disclosure relates to optoelectronic components and methods for producing optoelectronic components.

### SUMMARY

Various embodiments of the present disclosure relate to improved optoelectronic components. Various embodiments of the present disclosure relate to methods for producing an optoelectronic component with improved properties.

According to at least one embodiment, the optoelectronic component comprises a semiconductor chip which emits electromagnetic primary radiation of a first wavelength range during operation. The semiconductor chip is, for example, a flip chip in which both electrical contacts are arranged on one side of the semiconductor chip. The electrical contacts can also be located on the top and bottom of the semiconductor chip. During operation, the semiconductor chip can, for example, emit electromagnetic radiation from a wavelength range of UV radiation, visible light and/or infrared range. The semiconductor chip can emit electromagnetic radiation with a peak wavelength in a wavelength range of at least 400 nanometers to at most 1000 nanometers during operation. For example, the semiconductor chip may emit electromagnetic radiation with a peak wavelength in a wavelength range of at least 400 nanometers to at most 700 nanometers during operation.

According to at least one embodiment, the optoelectronic component comprises a semiconductor chip which, during operation, emits electromagnetic primary radiation of a first wavelength range in the range of 600-700 nm.

According to at least one embodiment, the optoelectronic component comprises at least one conversion element. The conversion element is formed in particular as a layer, encapsulation, platelet or film.

According to at least one embodiment, the conversion element is set up to emit electromagnetic secondary radiation of a second wavelength range. The second wavelength range differs at least in places from the first wavelength range.

According to at least one further embodiment, the electromagnetic secondary radiation is in the infrared spectral range. The optoelectronic component can emit broadband electromagnetic secondary radiation in the infrared spectral range. The wavelength range of the secondary radiation is in particular between 550 nm and 1800 nm, e.g., 700 nm to 1000 nm. This means that one peak wavelength of the secondary radiation in particular is in this wavelength range.

According to at least one embodiment, the conversion element comprises at least a wavelength converting material and a matrix material. The wavelength converting material partially converts the primary radiation of the semiconductor chip into secondary radiation, while a further part of the primary radiation of the semiconductor chip is transmitted by the conversion element. In particular, at least 90% of the emitted primary radiation of the semiconductor chip is converted into secondary radiation and at most 10% of the primary radiation of the semiconductor chip is transmitted by the conversion element.

The wavelength converting material can also convert the primary radiation of the semiconductor chip completely or almost completely into the secondary radiation. The optoelectronic component thus emits the electromagnetic secondary radiation in particular.

In particular, the matrix material is a polymer in which the absorption in the infrared spectral range is as low as possible. The matrix material can have a high transparency in the primary radiation range. In particular, the wavelength converting material is embedded in the matrix material. The wavelength converting material can be homogeneously embedded, i.e. evenly distributed in the matrix material.

According to at least one embodiment, the wavelength converting material is a Rylene dye. Rylene dyes are condensed naphthalene molecules. Rylene dyes have a high photostability and a high fluorescence quantum yield.

According to at least one embodiment, the optoelectronic component comprises a semiconductor chip which in operation emits electromagnetic primary radiation of a first wavelength range and at least one conversion element which is set up to emit electromagnetic secondary radiation of a second wavelength range and the electromagnetic secondary radiation is partly in the infrared spectral range, wherein the conversion element comprises at least one wavelength-converting material and a matrix material and the wavelength-converting material is a rylene dye.

According to at least one embodiment, the conversion element is arranged downstream of the semiconductor chip and an adhesion promoter layer is arranged between the conversion element and the semiconductor chip. The adhesion promoter layer comprises a transparent polymer, for example a silicone. The adhesion promoter layer is in particular a thin film. The conversion element is then mechanically bonded to the semiconductor chip in a particularly stable manner.

Alternatively, the conversion element can be in direct contact with the semiconductor chip. In this case, heat dissipation from the conversion element into the semiconductor chip is particularly good.

According to at least one embodiment, the component comprises a plurality of semiconductor chips. It is possible that a conversion element is arranged over only some of the semiconductor chips, while the other part of the semiconductor chips is free of a conversion element. The semiconductor chips that are free of a conversion element thus emit electromagnetic primary radiation. The total radiation emitted by the component can be composed of the electromagnetic primary radiation and the electromagnetic secondary radiation.

According to at least one embodiment, the rylene dye is selected from perylene, terylene, quarterylene or combinations thereof. Perylene comprises two condensed naphthalenes, terylene comprises three condensed naphthalenes and quarterylene comprises four condensed naphthalenes. The rylene dye has substituents in particular. The substituents are selected so that the rylene dye can be embedded particularly well in the matrix material. This means that the substituents of the rylene dye bind covalently to the matrix material, for example. This prevents the rylene dye from aggregating.

In particular, mixtures of two or more rylene dyes are used as wavelength converting material. This enables the broadest possible emission in the infrared spectral range to be achieved.

According to at least one embodiment, the wavelength converting material has the following structural formula:

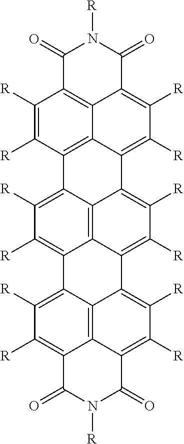

R is in each case independently selected from the group consisting of H atoms, halide atoms, D atoms, NO₂ groups, substituted and unsubstituted NH₂ groups, substituted and unsubstituted alkyl groups, substituted and unsubstituted alkenyl groups, aryloxy groups, substituted and unsubstituted aromatics, substituted and unsubstituted heteroaromatics, nitrile groups, CO₂R-groups and CONR₂-groups. R₂ is selected from H and alkyl groups, for example methyl, propyl or butyl groups. For example, R can be selected from the group of H atoms, halide atoms, D atoms, aryloxy groups, substituted and unsubstituted aromatics. For example, the substituted and unsubstituted aromatics are polycyclic aromatic hydrocarbons. Examples of these are naphthyl groups and anthracenyl groups. Alkenyl groups can be understood as a halidealkenyl group, for example a fluoroalkenyl group.

According to at least one embodiment, the wavelength converting material is selected from one of the following structural formulae:

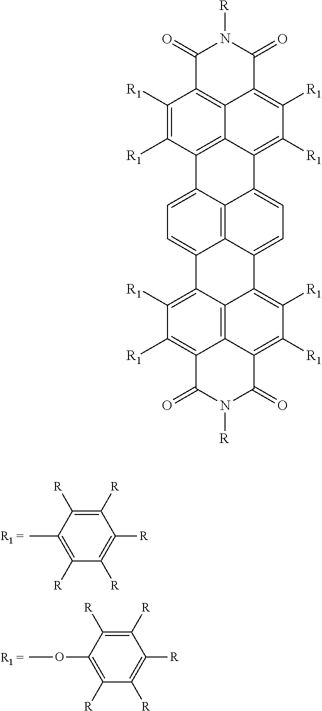

wherein each R is independently selected from the group consisting of H atoms, halide atoms, D atoms, substituted and unsubstituted alkyl groups, NO₂ groups, substituted and unsubstituted NH₂ groups, substituted and unsubstituted alkenyl groups, substituted and unsubstituted aromatics, substituted and unsubstituted heteroaromatics, nitrile groups, CO₂R-groups and CONR₂-groups and wherein Ri is selected from the structural formulae shown and from the group of H atoms, halide atoms and D atoms. A fluoroalkenyl group can be used as the alkenyl group. R₂ is selected from H and alkyl groups, for example methyl, propyl or butyl groups.

According to at least one embodiment, the wavelength converting material has the following structural formula:

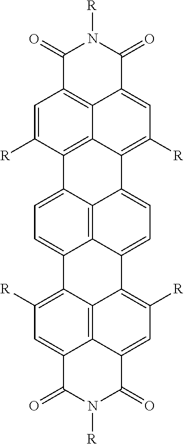

R is in each case independently selected from the group consisting of H atoms, halide atoms, D atoms, NO₂ groups, substituted and unsubstituted NH₂ groups, substituted and unsubstituted alkyl groups, substituted and unsubstituted alkenyl groups, aryloxy groups, substituted and unsubstituted aromatics, substituted and unsubstituted heteroaromatics, nitrile groups, CO₂R-groups and CONR₂-groups. R₂ is selected from H and alkyl groups, for example methyl, propyl or butyl groups. R can be selected from the group of halide atoms, D atoms, aryloxy groups, substituted and unsubstituted aromatics. R, for example, can be selected from the structural formulae shown above for R₁. For example, the substituted and unsubstituted aromatics are polycyclic aromatic hydrocarbons. Examples of these are naphthyl groups and anthracenyl groups.

According to at least one embodiment, the wavelength converting material has the following structural formula:

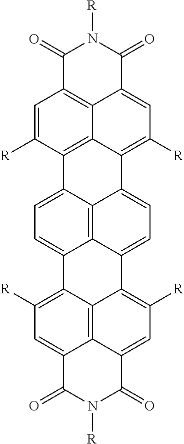

R is selected from the following structural formulae for R₁, wherein the residues R within R₁ are independently selected

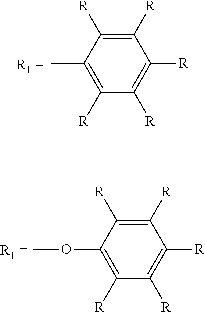

from the group consisting of H atoms, halide atoms, D atoms, and substituted and unsubstituted alkyl groups. The radicals R within R₁ can be independently selected from the group consisting of H atoms and substituted and unsubstituted alkyl groups.

According to at least one embodiment, the wavelength converting material is selected from one of the following structural formulae:

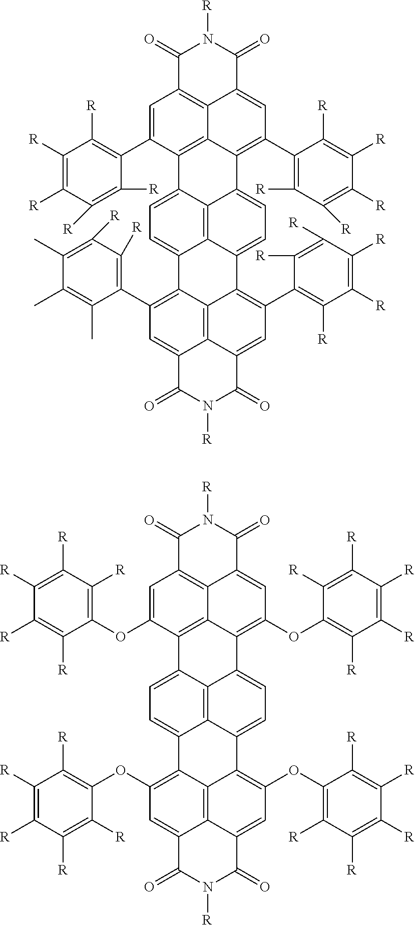

R is in each case independently selected from the group consisting of H atoms, halide atoms, D atoms, NO₂ groups, substituted and unsubstituted NH₂ groups, substituted and unsubstituted alkyl groups, substituted and unsubstituted alkenyl groups, aryloxy groups, substituted and unsubstituted aromatics, substituted and unsubstituted heteroaromatics, nitrile groups, CO₂R-groups and CONR₂-groups. R₂ is selected from H and alkyl groups, for example methyl, propyl or butyl groups. R can be selected from the group consisting of H 20 atoms, halide atoms, D atoms, substituted and unsubstituted aromatic groups and substituted and unsubstituted alkyl groups. For example, R can be selected from the group consisting of H atoms, substituted and unsubstituted aromatic compounds and substituted and unsubstituted alkyl groups.

According to at least one embodiment, the wavelength converting material is selected from one of the following structural formulae:

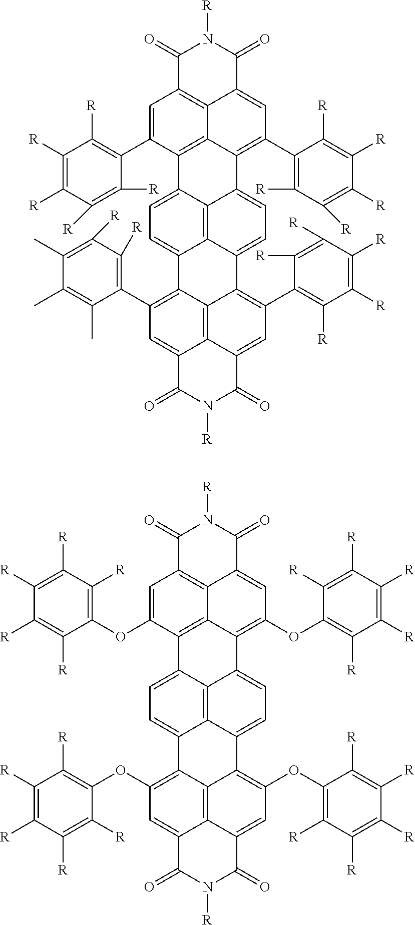

The residues R bonded to N are independently selected from the group consisting of substituted and unsubstituted aromatics, for example, substituted aromatics. In at least one example, the radicals R bound to N can correspond to R₁

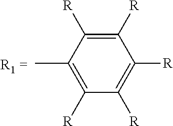

with

The radicals R bonded to C are selected independently of one another from the group consisting of H atoms, halide atoms, D atoms and substituted and unsubstituted alkyl groups.

According to at least one embodiment, the wavelength converting material is selected from one of the following structural formulae:

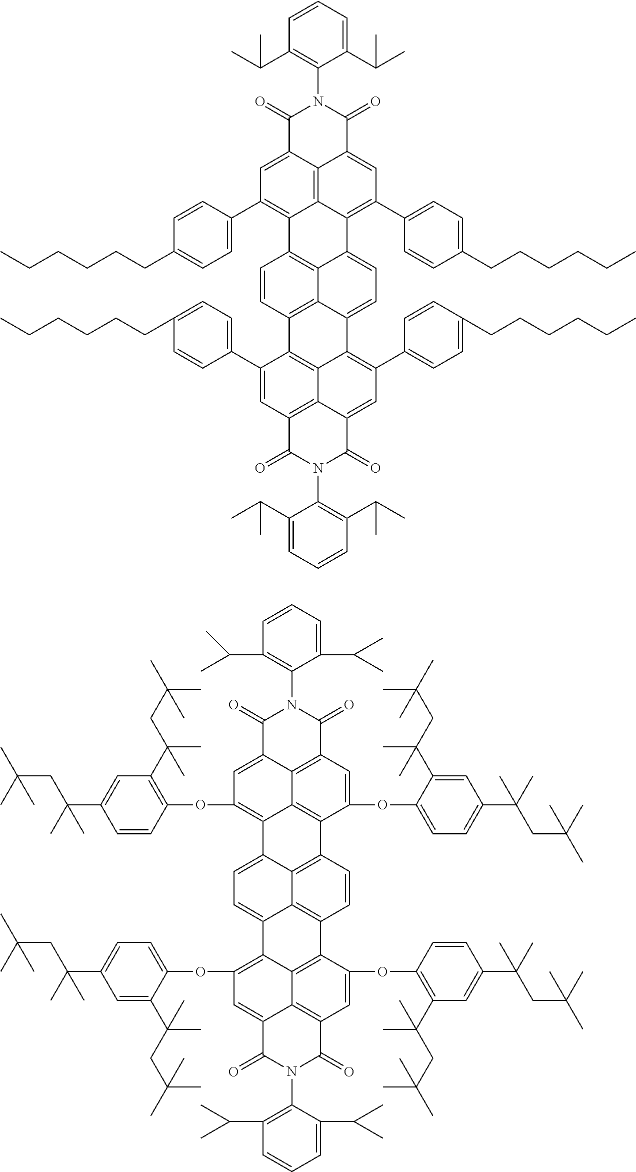

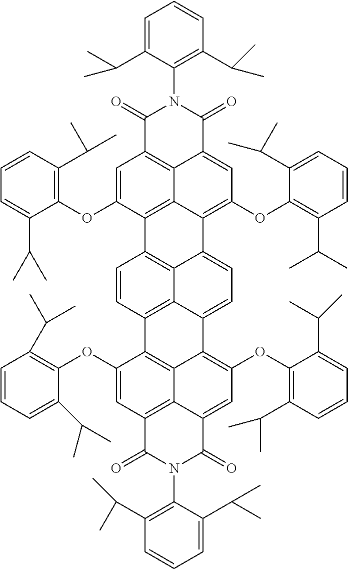 [SMILES: CC(C)c1cccc(C(C)C)c1Oc1cc2c3c(cc(Oc4c(C(C)C)cccc4C(C)C)c4c5ccc6c7c(Oc8c(C(C)C)cccc8C(C)C)cc8c9c(cc(Oc%10c(C(C)C)cccc%10C(C)C)c(c%10ccc(c1c34)c5c%106)c97)C(=O)N(c1c(C(C)C)cccc1C(C)C)C8=O)C(=O)N(c1c(C(C)C)cccc1C(C)C)C2=O]

The substituents on the Rylene dye mean that the wavelength converting material does not agglomerate in the matrix material. This prevents unwanted quenching effects. Furthermore, the substituents have different properties with regard to wavelength conversion.

The rylene dyes and the synthesis of the rylene dyes are described in the publication EP 21213300.3, the disclosure of which with regard to the synthesis of the rylene dyes is hereby incorporated by reference.

According to at least one embodiment, at least one H atom of the rylene dye is exchanged with an atom having a higher mass than hydrogen. This means that the rylene dye has at least one substituent which has a higher mass than hydrogen. The atom with a higher mass is in particular a halogen atom or a deuterium atom. For example, the atom with a higher mass is a fluorine atom and/or a deuterium atom.

This leads to a reduction in the oscillation energy. If the oscillation energy is reduced, the states can therefore overlap less at constant energy intervals, which leads to a reduction or suppression of the internal conversion. In wavelength converting materials, non-radiative transitions from the electronically excited state to the ground state can occur. The prerequisite for this is that the two electronic states are energetically superimposed, so that there is a transition from the vibrational ground state of the electronically excited state to a higher excited vibrational state of the electronic ground state. This superposition is all the more likely the smaller the distance between the electronic states, this means the greater the emission wavelength. Therefore, in at least one example, a wavelength converting material which has an atom with a higher mass than hydrogen partially or completely in the place of the hydrogen atom in the molecule can be used. This can be achieved, for example, by partial or complete deuteration or fluorination.

According to at least one embodiment, at least one or all of the wavelength converting materials in the conversion element has a concentration in a range between 0.01 wt % inclusive and 1.0 wt % inclusive. At least one or all of the wavelength converting materials in the conversion element can have a concentration in a range between 0.05 wt % inclusive and 0.5 wt %, inclusive. At least one wavelength converting material in the conversion element can have a concentration in a range between 0.01 wt % inclusive and 1.0 wt % inclusive.

The wavelength converting material can be used in a very low concentration. In order to increase the absorption of the primary radiation at these concentrations, the wavelength converting material can be excited by another wavelength converting material by means of a non-radiative energy transfer (FRET, Förster resonance energy transfer). Here, one or more wavelength converting materials, for example donor materials, can be linked to one or more wavelength converting materials, for example acceptor materials, covalently or via non-covalent interactions, for example hydrogen bonds, van der Waals interactions or electrostatic interactions.

In other words, differently absorbing rylene dyes can be linked together via chemical bonds. In these so-called multiple dyes, the energy is transferred from the shorter wavelength absorbing Rylene dye to the longer wavelength absorbing Rylene dye. The shape of the absorption band of the respective Rylene dye can also be influenced by targeted substitution. For example, aryloxy residues substituted in the ortho position cause an increase in the fluorescence quantum yields, which is why these residues are of particular interest as substituents for the longer wavelength absorbing, emitting rylene dye.

According to at least one embodiment, the matrix material is selected from epoxides, silicones, fluorosilicones, polymethyl methacrylates, polysiloxanes, polycarbonates, melting gels, glass or combinations thereof. The matrix material can be selected from epoxides, silicones, glass or combinations thereof. In particular, the matrix material is transparent. In particular, the wavelength converting material is covalently or non-covalently bonded to the matrix material, for example via hydrogen bonds, electrostatic bonds or van der Waals bonds. This can have the advantage of preventing agglomeration of wavelength converting materials.

According to at least one embodiment, the matrix material is a silicone. The silicone can contain a platinum compound. Such silicones can be particularly resistant to infrared radiation.

Melting gels are described in the document J. Sol-Gel Sci. Technol. (2010) 55:86-93. Melting gels are a class of organically modified silica gels that are rigid at room temperature. At a temperature Tl the melting gels flow and at a temperature T2 they solidify. The process of softening, solidification and re-softening can be repeated many times. Organically modified silica gels are, for example, monosubstituted alkoxysilanes and disubstituted alkoxysilanes.

According to at least one embodiment, a dichroic mirror is arranged on the side of the conversion element facing away from the semiconductor chip. The dichroic mirror is in particular a thin film. The dichroic mirror has, for example, a vaporized glass which selectively reflects certain wavelengths and transmits other wavelengths. In particular, the mirror has the task of increasing the absorption and subsequent conversion of the primary radiation of the semiconductor chip in the conversion element. In particular, the dichroic mirror comprises SiO₂/Al₂O₃ layers. The dichroic mirror can have the advantage that the concentration of wavelength converting materials used can be kept low. Higher concentrations of the wavelength converting material in the conversion element lead to a reduction in quantum efficiency, as the wavelength converting materials are deposited together. An adhesion promoter layer is optionally applied between the dichroic mirror and the conversion element.

According to at least one embodiment, the semiconductor chip and the conversion element are overmolded by an encapsulation. In particular, the encapsulation is gas-tight and moisture-resistant. The encapsulation comprises, for example, a metal oxide, such as, Al₂O₃, SiO₂, TiO₂, MgO, ZrO₂, Zno and combinations thereof, or a metal nitride, such as, Si₃N₄, AlN and BN. The thickness of the encapsulation can be in a range from 2 inclusive to 500 nm inclusive. The thickness of the encapsulation can be in a range from 15 nm inclusive to 50 nm inclusive. The semiconductor chip and the conversion element can also be surrounded laterally by the encapsulation. The encapsulation can be applied for example by chemical vapor deposition, by atomic layer deposition, by plasma-enhanced chemical vapor deposition, by physical vapor deposition, by organometallic vapor phase epitaxy, by electron beam processing, by molecular beam epitaxy, electrolytically or wet-chemically.

According to at least one embodiment, the primary radiation is in a wavelength range between 550 nm inclusive and 1000 nm inclusive. The energy difference between the primary radiation and the secondary radiation can be minimized. This means that a maximum emission of the primary radiation is at a wavelength that is as close as possible to the emission spectrum of the secondary radiation. The emission maximum is the wavelength at which the wavelength converting material or the semiconductor chip exhibits the greatest emission. For example, the energy difference is less than 0.5 eV, for example, less than 0.25 eV and less than 0.1 eV.

An excitation wavelength of the wavelength converting materials is in particular between 550 nm inclusive and 1000 nm inclusive. In at least one example, the wavelength converting material can have an absorption maximum in a wavelength range between 600 nm inclusive and 700 nm inclusive. In particular, the absorption maximum is a local absorption maximum. The quantum efficiency can be greater than 10%.

An InGaAlP semiconductor chip is used as the semiconductor chip for wavelengths in the range from 550 nm inclusive to 800 nm inclusive. Above 800 nm, an InGaAs/AlGaAs semiconductor chip can be used. The materials gallium, indium and arsenic shift the emission to longer wavelengths and aluminum and phosphorus to shorter wavelengths. A half width can be in a range between 10 nm inclusive and 40 nm inclusive.

According to at least one embodiment, the semiconductor chip is a micro LED chip. In particular, the micro LED chip has a pixel size of less than 100 μm by 100 μm. The pixel size can be larger than 1 μm by 1 μm.

Compared to conventional inorganic phosphors, the dyes according to examples of the present disclosure can also be used for micro LED chips. Inorganic phosphors have typical particle sizes of 5 μm to 100 μm, which means, among other things, that the aspect ratios cannot be reproduced. Likewise, the rylene dyes according to examples of the present disclosure have a higher absorption at a same layer thickness of the conversion material, e.g. thinner than 20 μm. The electromagnetic primary radiation emitted by the semiconductor chip can be partially or completely (i.e. >95%) converted into a secondary radiation with a thin conversion layer or conversion element.

According to at least one embodiment, the optoelectronic component has a plurality of micro LED chips. The micro-LED chips can have a rectangular or square base and/or emission area. It is also possible for the micro-LEDs to have a round base and/or emission area. The base area of a micro-LED chip can be smaller than 0.01 mm².

According to at least one embodiment, the plurality of micro-LED chips in an optoelectronic component are connected by a common substrate or carrier. The substrate or the carrier can serve as a common electrical connection of the micro-LEDs. The carrier or the substrate may contain electronic components, such as IC and/or CMOS. The common substrate or the common carrier may be an epitaxially grown semiconductor layer. For example, this layer can consist of any combination of (In, Al, Ga) and (N, As, P, Sb).

According to at least one embodiment, the plurality of micro-LED chips in an optoelectronic component are designed such that emissions can be generated in the entire visible and near-infrared spectrum (e.g., from 400 nm-2000 nm). This emission spectrum can be achieved, for example, by combining the emissions of blue, green, red, near-infrared and infrared emitting micro-LED chips, as well as the combination of micro-LED chips and semiconductor chips. In particular, it is possible that a conversion element is only arranged above one part of the micro-LED chips or semiconductor chips, while the other part of the micro-LED chips or semiconductor chips is free of a conversion element.

According to at least one embodiment, the micro-LED chips are combined with at least one detector. The at least one detector can be arranged inside or outside the optoelectronic component. The at least one detector can be designed as a sensor.

According to at least one embodiment, the primary radiation is less than 550 nm. In particular, the primary radiation is in a wavelength range from 350 nm up to and including 550 nm. Here, for example, an InGaN semiconductor chip is used. The InGaN semiconductor chip emits primary radiation in the wavelength range from 420 nm to 470 nm. The emitted primary radiation can be converted into secondary radiation by more than 90%, for example by more than 95%. AlInGaN semiconductor chips can also be used. The primary radiation of the AlInGaN semiconductor chip can be adjusted by the concentration of indium. In particular, the primary radiation is between 380 nm and 560 nm inclusive. The half-width lies in a range between 10 nm inclusive and 30 nm inclusive and can also be set to an accuracy of 1 nm. The secondary radiation is in a wavelength range between 550 nm inclusive and 1000 nm inclusive.

According to at least one embodiment, at least 50% of the emitted secondary radiation is in a wavelength range between 700 nm inclusive and 1000 nm inclusive. At least 80% of the emitted secondary radiation can be in a wavelength range between 700 nm inclusive and 1000 nm inclusive. In other words, the conversion element converts at least 50%, e.g., at least 80%, of the primary radiation into secondary radiation in a wavelength range between 700 nm inclusive and 1000 nm inclusive. The secondary radiation is thus in the infrared spectral range.

According to at least one embodiment, an inorganic phosphor is embedded in the matrix material. In particular, the inorganic phosphor emits in the wavelength range of greater than or equal to 750 nm. The inorganic phosphor can be excited by the primary radiation of the semiconductor chip and/or by the already converted secondary radiation of the wavelength converting material. The inorganic phosphor is, for example, a ceramic or crystalline phosphor. In particular, the ceramic and crystalline phosphors have a garnet phosphor, a nitride phosphor or a combination thereof. Examples of phosphors are shown below:

Cr³⁺, Sm³⁺, Yb³⁺, Nd⁺, Bi²⁺, Dy³⁺, Ho³⁺, Ni²⁺, Zr⁴⁺, Cr⁴⁺, Ca²⁺, Er³⁺ and/or Tm³⁺ doped phosphors of the general formulas RE₃ (Al, Ga, Sc)₅O₁₂, Ca₃Al₂Ge₂O₁₀, Ca₁₄Zn₆Al₁₀O₃₅, LiAl₅O₈, Sr₂MgAl₂₂O₃₆, SrMgAl₁₀O₁₇, Ca₁₄Zn₆Ga₁₀O₃₅, Mg₃Ga₂GeO₈, ZnGa₂O₄, β-Ga₂O₃, Gd₃Ga₅O₁₂, La₃Ga₅GeO₁₄, Mg₃Ga₂GeO₈, Zn_{1.25}Ga_{1 5}Ge_{0.25}O₄, LiGa₅O₈, InMgGaO₄, LiTaO₃, LilnSi₂O₆, SrSc₂O₄, CaSc₂O₄, GdScO₃, Na₂CaSn₂Ge₃O₁₂, Na₂CaTi₂Ge₃O₁₂, NaMg₃Al (MoO₄)₅, BaZrSi₃O₉, Cs₂NaAIF₆, NaAIF₆, Ca₂LuZr₂Al₃O₁₂, La₂MgZrO₆, ZnAl₂S₄, Sr₈MgLa(PO₄)₇, Ca₂GaNbO₆, Ca₂AINbO₆.

The nitride phosphor can be, for example, an alkaline earth silicon nitride, an oxynitride, an aluminum oxynitride, a silicon nitride or a sialon. For example, the nitride phosphor is La₃Si₆N₁₁:Ce³⁺ (LSN), (La, Y)₃Si₆N₁₁:Ce³⁺ (LYSN), Sr[Si₂Li₂N₂O₂]:Eu, (Sr, Ba) SiON:Eu, α-SiAlON:Eu, β-SiAlON:Eu, (Ca, Sr, Ba)AlSiN₃:Eu²⁺ (CASN), Sr(Ca, Sr) Al₂Si₂N₆:Eu²⁺ (SCASN) or M₂Si₅N₈:Eu²⁺ with M=Ca, Ba or Sr alone or in combination.

According to at least one embodiment, a quantum dot and/or a nanoparticle is embedded in the matrix material. For example, CdS, CdSe, CdTe, ZnS, ZnSe, ZnTe, HgTe, HgSe, GaP, GaAs, GaSb, AIP, AIAs, AISb, InP, InAs, InSb, GaSb, SiC, InN, AIN, GaN, BN, Zno, MgO, InSnO., Sno: or their mixed crystals can be used as the semiconductor material for the quantum dots. In particular, a combination of several different semiconductor materials can be used.

The semiconductor material can have a band gap corresponding to wavelengths in the range from 900 nm up to and including 2 um. Core shell architectures can also be used as semiconductor material for the quantum dots. The energy difference in the band gap between the core semiconductor material and the shell material is 0.5 eV, for example. The band gap of the embedding material can be larger. The semiconductor material used for the shell material is, for example, CdS, CdSe, CdTe, ZnS, ZnSe, ZnTe, HgTe, HgSe, GaP, GaAs, GaSb, AlP, AlAs, AlSb, InP, InAs, InSb, SiC, InN, AlN, their mixed crystals or a combination of several different semiconductor materials. The embedding of quantum dots in the conversion element means that the emitted secondary radiation can be specifically adjusted.

The nanoparticles are selected in particular from the group of metal oxides and metal nitrides. For example, the nanoparticles are amorphous or polycrystalline compounds. The nanoparticles are, for example, metal oxides, such as, Al₂O₃SiO₂, TiO₂, MgO, ZrO₂, Zno and combinations thereof and/or metal nitrides, such as, Si₃N₄, AlN and BN. By embedding the nanoparticles in the conversion element, the light scattering in the conversion element can be adjusted.

According to at least one embodiment, the surface of the conversion element has an outcoupling structure. In particular, the surface of the conversion element has an uneven structure. For example, there is a pyramid-shaped structure on the surface of the conversion element. In particular, the surface of the conversion element can have a regular 3D structure. The outcoupling structure leads to an improved light extraction. The outcoupling structure is created, for example, by etching, stamping, scribing or laser ablation.

According to at least one embodiment, at least two conversion elements are arranged downstream of the semiconductor chip, wherein a first conversion element of the at least two conversion elements, which is arranged closer to the semiconductor chip, comprises a first rylene dye whose secondary radiation is in the longer wavelength range than the secondary radiation of a second rylene dye in a second conversion element of the at least two conversion elements, which is further away from the semiconductor chip. This means, for example, that the optoelectronic component comprises two conversion elements and the first conversion element comprises the first rylene dye and the second conversion element comprises the second rylene dye. The first rylene dye differs from the second rylene dye in that the first rylene dye converts the primary radiation of the semiconductor chip into secondary radiation in the longer wavelength range. The first conversion element with the first rylene dye is arranged closer to the semiconductor chip. The different conversion properties of the Rylene dyes can be adjusted by the substituents on the Rylene dyes.

It is also possible that more than two conversion elements are arranged on the semiconductor chip. An adhesion promoter layer can be arranged between the conversion elements. It is also possible for two conversion elements with the same Rylene dye to be arranged on top of each other. The reason for this is that the individual conversion elements can only have a certain maximum concentration of Rylene dyes. If the concentration is too high, quenching effects would occur.

In particular, inorganic phosphors, quantum dots and/or nanoparticles are embedded in the conversion elements.

A method for producing an optoelectronic component is further disclosed. In particular, the method for producing an optoelectronic component described herein can be used to produce an optoelectronic component described herein. That is, all features disclosed for the method for producing optoelectronic components are also disclosed for the optoelectronic component and vice versa.

According to at least one embodiment of the method for producing an optoelectronic component, a semiconductor chip is provided which is set up to emit primary radiation of a first wavelength range during operation. In a further step of the method, a conversion element described herein is produced, which is set up to emit secondary radiation of a second wavelength range and the electromagnetic secondary radiation is in the infrared spectral range. In a further step, the conversion element is applied to the semiconductor chip.

According to at least one embodiment, the conversion element is applied to a substrate before being applied to the semiconductor chip and the conversion element and the substrate are separated. The substrate is in particular a transparent substrate. The transparent substrate is, for example, a glass, a ceramic, a plastic, a silicone or a sapphire.

A plurality of substrates with the conversion element or the divided substrates with the conversion element are applied to the semiconductor chip. The conversion element can be applied to the semiconductor chip with the side facing away from the substrate. For example, the substrate is detached from the conversion element after application.

For example, a large number of conversion elements are applied to the substrate. In this way, an optoelectronic component with a large number of conversion elements can be obtained. Finally, for example, a dichroic mirror is applied to the conversion element.

One idea of the present optoelectronic component is to emit light in the infrared spectral range. An optoelectronic component described here is used in the field of sensors, monitoring and miniature spectrometers. Miniature spectrometers are of interest for various applications, for example food analysis or biomonitoring. In particular, microspectrometers can be used in smartphones.

Furthermore, the use of primary radiation with a wavelength greater than 550 nm can lead to reduced losses due to the energy difference from excitation to emission. In addition, the use of a non-particulate, wavelength converting material results in reduced losses due to scattering.

The use of a combination of wavelength converting materials and a quantum dot can allow the wavelength of the emitting spectrum to be set more flexibly and optimized for the application.

Furthermore, the amount of heavy metal-containing quantum dots in an optoelectronic component is limited by the RoHS (Restriction of Hazardous Substances) directives. In combination, an advantageous spectral design can be achieved while complying with legal hazardous substance requirements.

### BRIEF DESCRIPTION OF THE DRAWINGS

Further embodiments of the optoelectronic component and of the method for producing an optoelectronic component result from the exemplary embodiments described below in conjunction with the figures below:

FIGS. 1, 3 and 8 show schematic sectional views of an optoelectronic component according to one exemplary embodiment in each case,

FIG. 2 shows a top view of an optoelectronic component according to an exemplary embodiment,

FIGS. 4 and 12 shows emission spectra of an optoelectronic component according to one exemplary embodiment in each case,

FIGS. 5, 6, 7, 9, 10, 11 and 13 each show an emission spectrum of an optoelectronic component and a schematic sectional view of an optoelectronic component according to a respective exemplary embodiment,

FIG. 14 shows a transmission spectrum of a dichroic mirror, and

FIG. 15 shows a method for producing an optoelectronic component according to an exemplary embodiment.

Elements that are identical, similar or have the same effect are marked with the same reference symbols in the figures. The figures and the proportions of the elements shown in the figures should not be considered to be to scale. Rather, individual elements, in particular layer thicknesses, may be shown in exaggerated size for better visualization and/or understanding.

### DETAILED DESCRIPTION

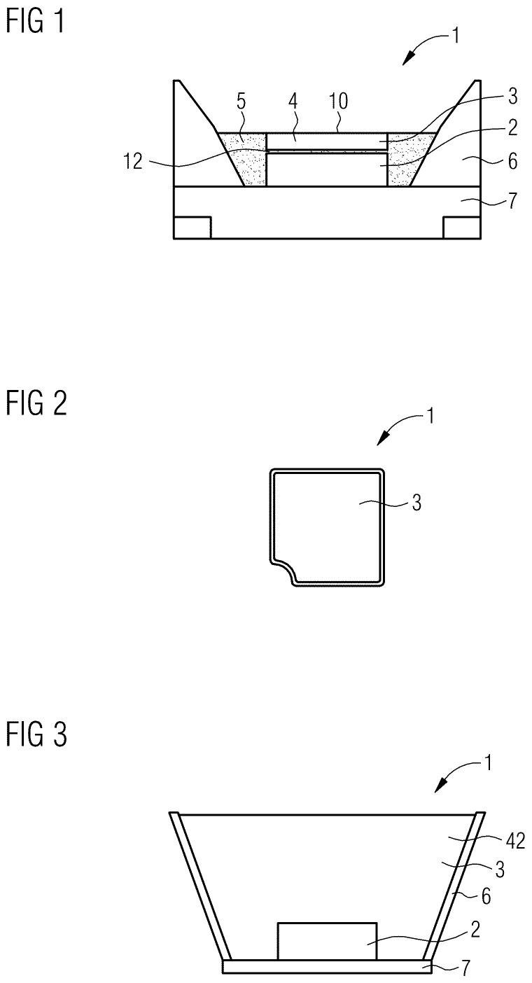

The optoelectronic component 1 according to the exemplary embodiment of FIG. 1 comprises a semiconductor chip 2 and a conversion element 3. The conversion element 3 is applied directly to the top of the semiconductor chip 2. An adhesion promoter layer 12 is optionally arranged between the conversion element 3 and the semiconductor chip 2. The adhesion promoter layer 12 comprises, for example, a silicone. The semiconductor chip 2 and the conversion element 3 are laterally surrounded by a surrounding 5. The surrounding 5 comprises titanium dioxide and a matrix material, for example silicone. The semiconductor chip 2 is arranged on a carrier 7. The surrounding 5 is laterally surrounded by a housing 6. Optionally, the semiconductor chip 2 and the conversion element 3 can be encapsulated.

The conversion element 3 comprises at least one wavelength converting material 4 and a matrix material 5. The wavelength converting material 4 is a rylene dye. The rylene dye is selected from perylene, terylene, quarterylene or combinations thereof. The wavelength converting material 4 can include a terylene dye. The wavelength converting material 4 comprises the following structural formula:

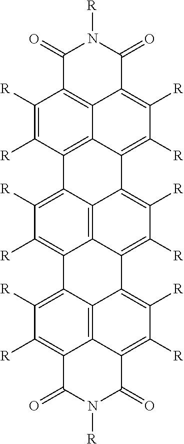

R is in each case independently selected from the group consisting of H atoms, halide atoms, D atoms, NO₂ groups, substituted and unsubstituted NH₂ groups, substituted and unsubstituted alkyl groups, substituted and unsubstituted alkenyl groups, aryloxy groups, substituted and unsubstituted aromatics, substituted and unsubstituted heteroaromatics, nitrile groups, CO₂R-groups and CONR₂-groups. R₂ is selected from H and alkyl groups, for example methyl, propyl or butyl groups. R can be selected from the group of H atoms, halide atoms, D atoms, aryloxy groups, substituted and unsubstituted aromatics. Alkenyl groups can be understood as a halidealkenyl group, for example a fluoroalkenyl group.

The wavelength converting material 4 is selected, for example, from one of the following structural formulae:

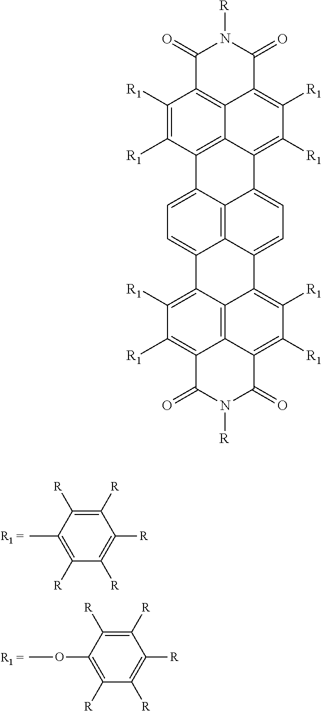

wherein each R is independently selected from the group consisting of H atoms, halide atoms, D atoms, substituted and unsubstituted alkyl groups, NO₂ groups, substituted and unsubstituted NH₂ groups, substituted and unsubstituted alkenyl groups, substituted and unsubstituted aromatics, substituted and unsubstituted heteroaromatics, nitrile groups, CO₂R-groups and CONR₂-groups. R₂ is selected from H and alkyl groups, for example methyl, propyl or butyl groups. In addition to the structural formulae shown above, R₁ can also be selected from the group of H atoms, halide atoms and D atoms.

The first rylene dye 41, the second rylene dye 42 and the third rylene dye 43 are shown below:

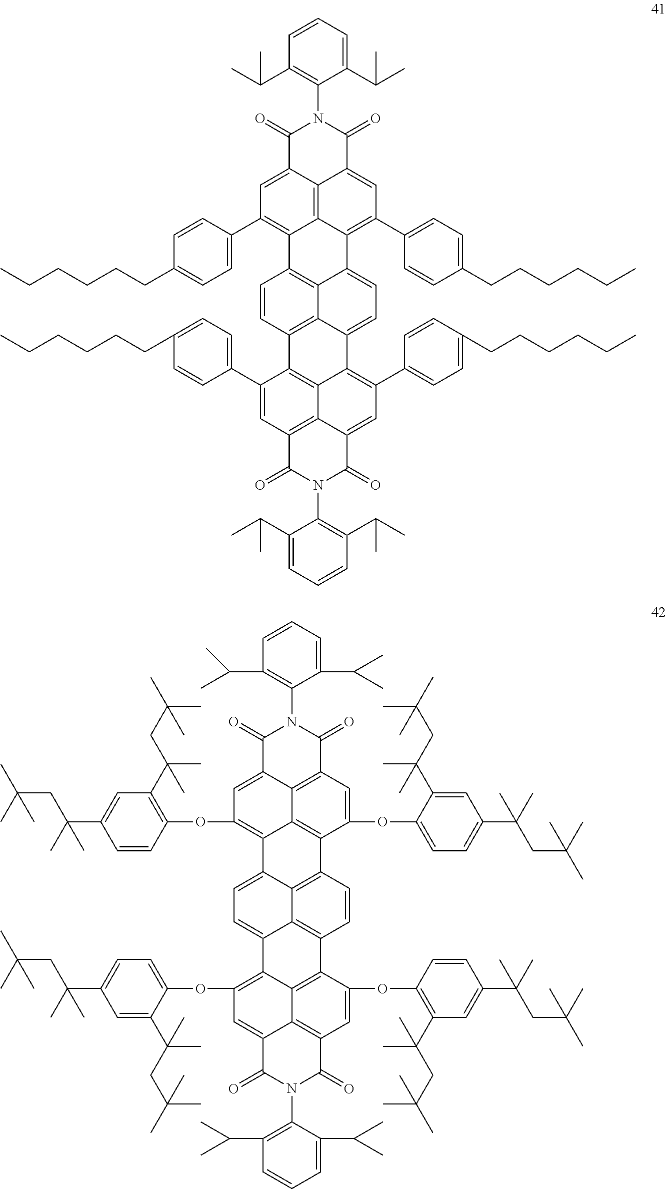

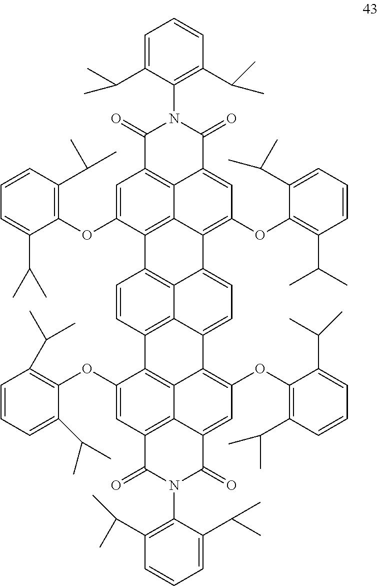 [SMILES: CC(C)c1cccc(C(C)C)c1Oc1cc2c3c(cc(Oc4c(C(C)C)cccc4C(C)C)c4c5ccc6c7c(Oc8c(C(C)C)cccc8C(C)C)cc8c9c(cc(Oc%10c(C(C)C)cccc%10C(C)C)c(c%10ccc(c1c34)c5c%106)c97)C(=O)N(c1c(C(C)C)cccc1C(C)C)C8=O)C(=O)N(c1c(C(C)C)cccc1C(C)C)C2=O]

The different substituents on the Rylene dye mean that the wavelength converting material 4 does not agglomerate in the matrix material 5. This prevents unwanted quenching reactions. Furthermore, the substituents have different properties with regard to wavelength conversion.

In the case of the Rylene dye, a hydrogen atom can also be exchanged with an atom with a higher mass than hydrogen. The atom with a higher mass is a deuterium atom and/or a fluorine atom.

At least one or all of the wavelength converting materials 4 in the conversion element 3 comprise a concentration in a range between 0.01 wt % inclusive and 1 wt %, inclusive. If the concentration of wavelength-converting materials 4 is too high, the wavelength-converting materials 4 will be clustered together, resulting in a quenching effect.

The rylene dyes are selected so that they can bind particularly well to the matrix material 5 with covalent and/or coordinative bonds and thus prevent the wavelength-converting materials 4 from aggregating. The matrix material 5 here is a polycarbonate.

The optoelectronic component 1 emits secondary radiation in the infrared spectral range. The secondary radiation is in a wavelength range between 700 nm inclusive and 1000 nm inclusive. The primary radiation emitted by the semiconductor chip 2 is in a wavelength range between 550 nm inclusive and 1000 nm inclusive. Alternatively, the wavelength of the primary radiation emitted by the semiconductor chip 2 may be less than 550 nm.

In addition to the wavelength converting material 4, an inorganic phosphor and/or a quantum dot and/or a nanoparticle can be embedded in the conversion element 3. The surface of the conversion element 3 has, for example, an outcoupling structure 10. The outcoupling structure 10 is uneven, for example.

The exemplary embodiment of FIG. 2 shows a top view of an optoelectronic component 1. The conversion element 3 with a wavelength converting material 4 can be seen here.

FIG. 3 shows a schematic sectional view of an optoelectronic component 1 according to an exemplary embodiment. The optoelectronic component 1 of FIG. 3 differs from the optoelectronic component 1 of FIG. 1 in that the conversion element 3 is designed as an encapsulation. The conversion element 3 surrounds the semiconductor chip 2 laterally and at the top of the semiconductor chip 2. The wavelength converting material 4 of the conversion element 3 of FIG. 3 has the structural formula of the second rylene dye 42.

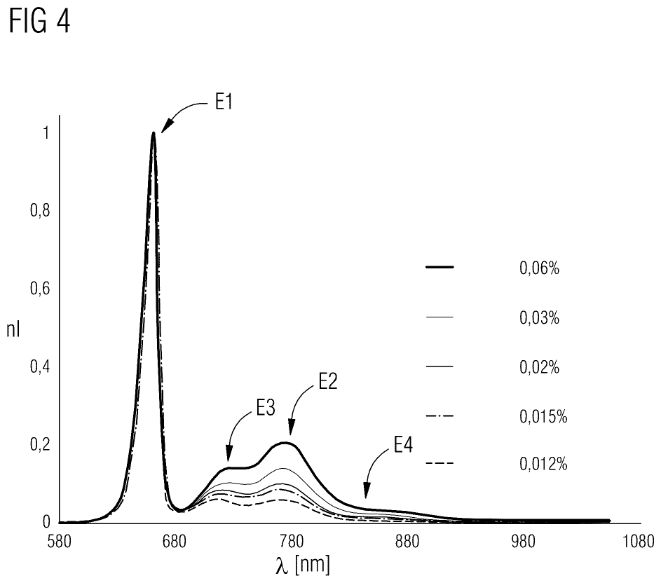

FIG. 4 shows five emission spectra of the optoelectronic component 1 of FIG. 3. The emission spectrum is the normalized, spectral intensity nI of the electromagnetic radiation emitted by the optoelectronic component 1 as a function of the wavelength A. The emission spectra have four emission maxima E1, E2, E3 and E4. The wavelength of the emission maximum E1 is between 630 nm and 680 nm. The wavelength of the emission maximum E2 is between 730 nm and 820 nm and the wavelength of the emission maximum E3 is between 680 nm and 730 nm. The fourth emission maximum E4 is around 850 nm. The fourth emission maximum E4 is less intense compared to the emission maxima E2 and E3. The emission maximum E1 shows the primary radiation of the semiconductor chip 2, which has not been converted. The emission maxima E2 and E3 show the secondary radiation of the wavelength converting material 4.

The five different emission spectra were obtained with five different optoelectronic components 1. The concentration of the wavelength converting material 4 in the conversion element 3 was varied. The concentration of the wavelength converting material 4 varies from 0.06 wt % to 0.012 wt %. At a lower concentration, a low intensity is also obtained in the emission of the secondary radiation. However, the intensity of the emission can be controlled by the size of the optoelectronic component even at a constant concentration. This means that the intensity can also be controlled by the length of the light path.

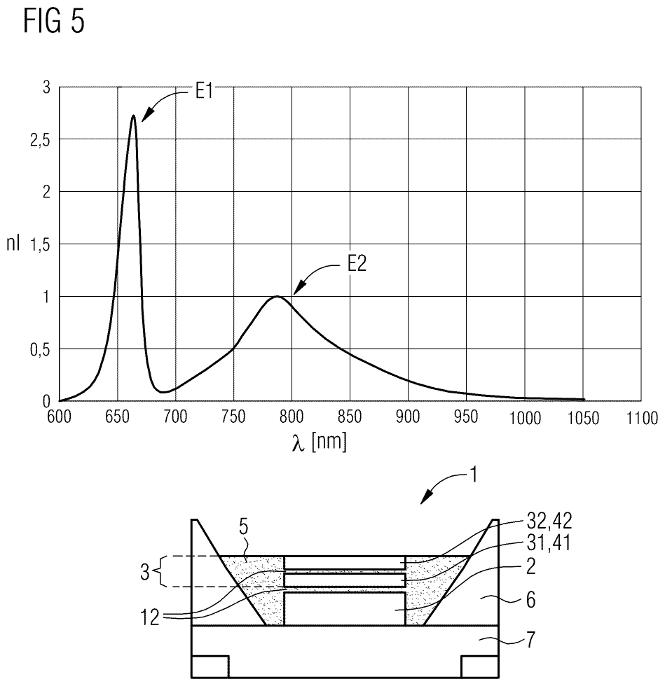

FIG. 5 shows an emission spectrum and a schematic sectional view of an optoelectronic component 1 according to an exemplary embodiment. Compared to FIG. 1, the optoelectronic component 1 shows a first conversion element 31 and a second conversion element 32. The conversion elements 3 are formed as foils. An adhesion promoter layer 12 is optionally arranged between the conversion elements 3. The first conversion element 31 comprises the first rylene dye 41. The second conversion element 32 comprises the second rylene dye 42. The first conversion element 31 is arranged closer to the semiconductor chip 2 than the second conversion element 32. The first rylene dye 41 comprises a secondary radiation in the longer wavelength range than the secondary radiation of the second rylene dye 42.

The adjacent emission spectrum shows the emission of the optoelectronic component 1. The normalized intensity nI is plotted against the wavelength λ. Two emission maxima E1 and E2 can also be seen here. The emission maximum E1 is between 640 nm and 700 nm and the second emission maximum E2 is between 750 nm and 850 nm.

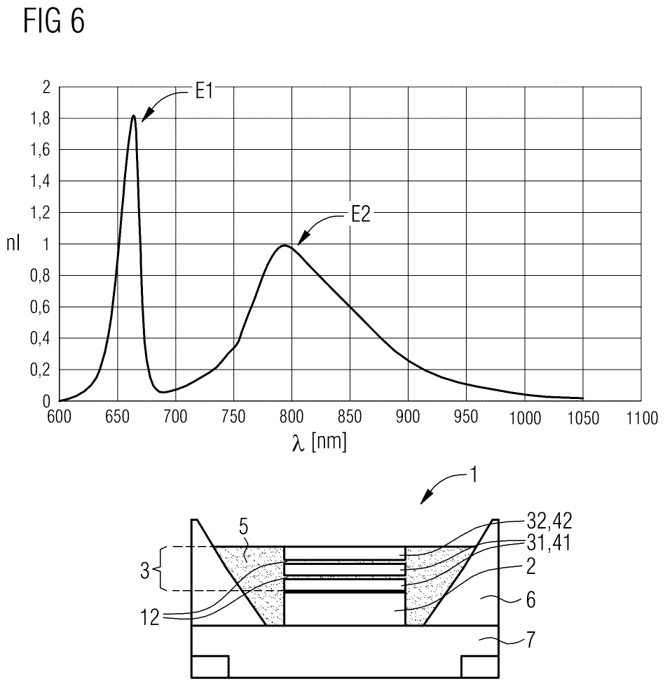

The exemplary embodiment of FIG. 6 shows an optoelectronic component 1 according to an exemplary embodiment. Compared to the exemplary embodiment of FIG. 5, the optoelectronic component 1 comprises two first conversion elements 31 and a second conversion element 32. The first conversion elements 31 comprise a first rylene dye 41 and the second conversion element 32 comprises a second rylene dye 42.

FIG. 6 also shows an emission spectrum of the adjacent optoelectronic component 1. Two emission maxima E1, E2 are also shown here. The first emission maximum E1 is between 650 nm and 700 nm and shows the primary radiation of the semiconductor chip 2. The second emission maximum E2 is between 770 nm and 810 nm and shows the secondary radiation in the infrared spectral range.

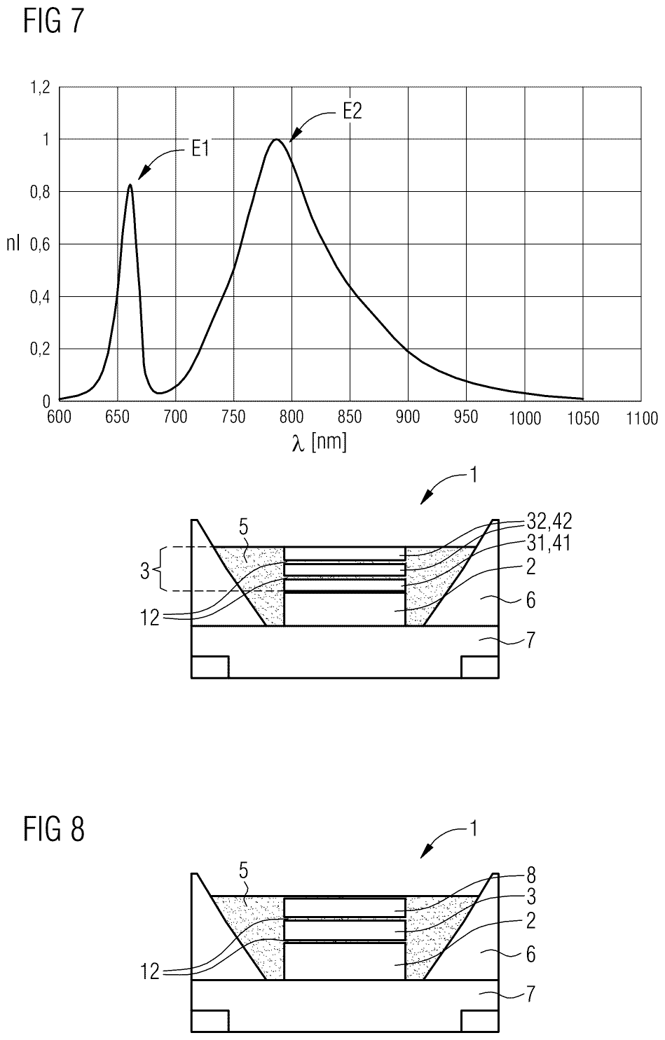

The exemplary embodiment shown in FIG. 7 shows an optoelectronic component 1 with a first conversion element 31 and two second conversion elements 32. The first conversion element 31 arranged directly on the semiconductor chip 2 comprises the first rylene dye 41 and the two subsequently arranged second conversion elements 32 comprise the second rylene dye 42.

The adjacent emission spectrum in FIG. 7 also shows two emission maxima E1 and E2. The first emission maximum E1 is between 650 nm and 670 nm and the second emission maximum E2 is between 760 nm and 810 nm.

In the exemplary embodiment shown in FIG. 8, a dichroic mirror 8 is also arranged on the conversion element 3. The dichroic mirror 8 has layers of SiO₂/Al₂O₃. The conversion element 3 can have several conversion elements 3.

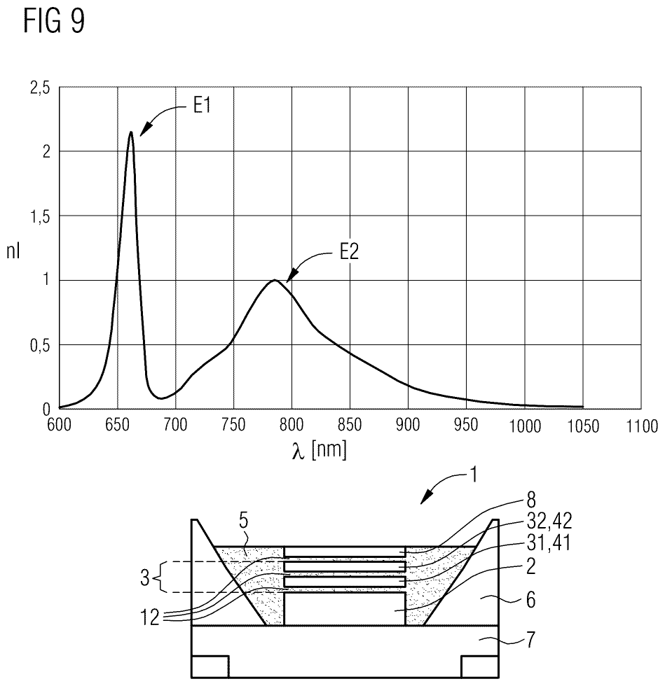

The exemplary embodiment of FIG. 9 shows a conversion element comprising a first conversion element 31 with a first rylene dye 41 and a second conversion element 32 with a second rylene dye 42. The first conversion element 31 is located between the second conversion element 32 and the semiconductor chip 2. A dichroic mirror 8 is located on the side of the second conversion element 32 facing away from the semiconductor chip 2. The dichroic mirror 8 is intended to reflect primary radiation emitted by the semiconductor chip 2 until it is converted by the wavelength converting material 4. The converted radiation is then emitted by the optoelectronic component 1. An emission spectrum with two emission maxima E1 and E2 is also shown here.

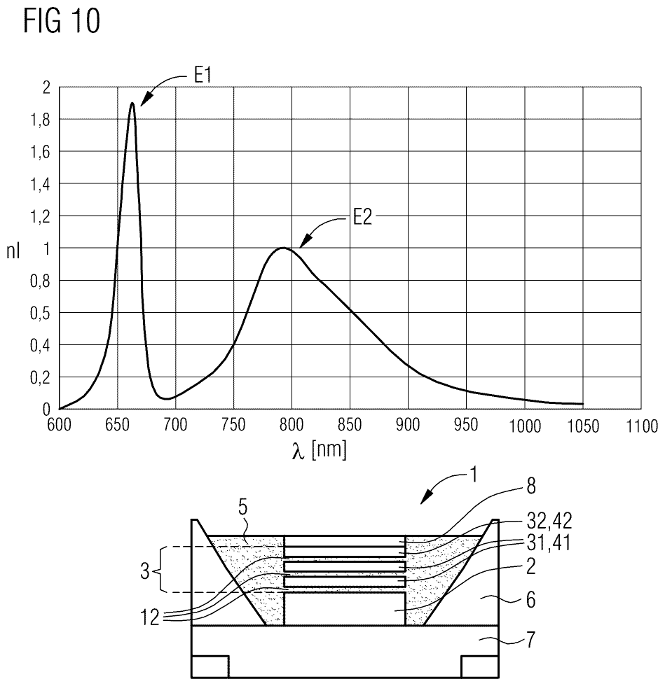

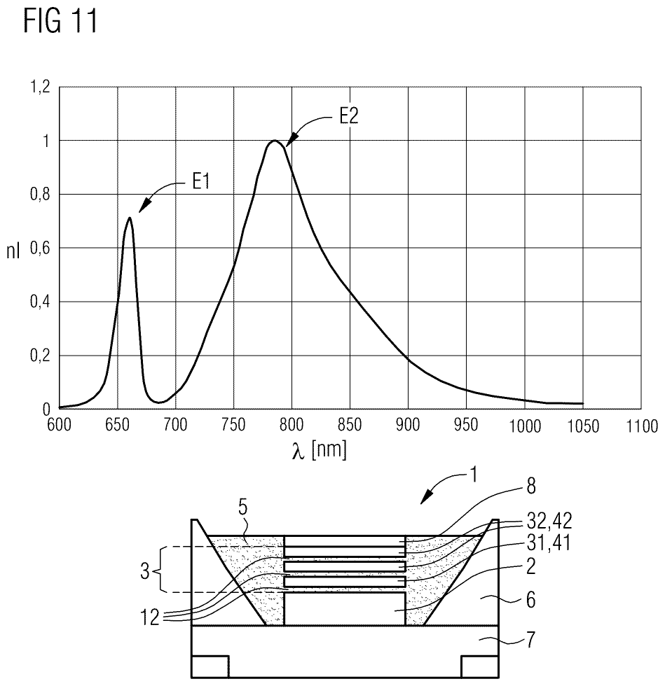

FIGS. 10 and 11 also show an optoelectronic component 1 according to one exemplary embodiment in each case. FIGS. 10 and 11 differ in that two first conversion elements 31 and a second emission element 32 are shown in FIG. 10 and one first conversion element 31 and two second conversion elements 32 are shown in FIG. 11. Both optoelectronic components 1 have a dichroic mirror 8.

An emission spectrum is shown next to each of the sectional views of the optoelectronic components 1. Both emission spectra show two emission maxima E1 and E2. A first emission maximum E1 lies in a wavelength range between 650 nm and 680 nm and a second emission maximum E2 lies in a wavelength range between 770 nm and 810 nm.

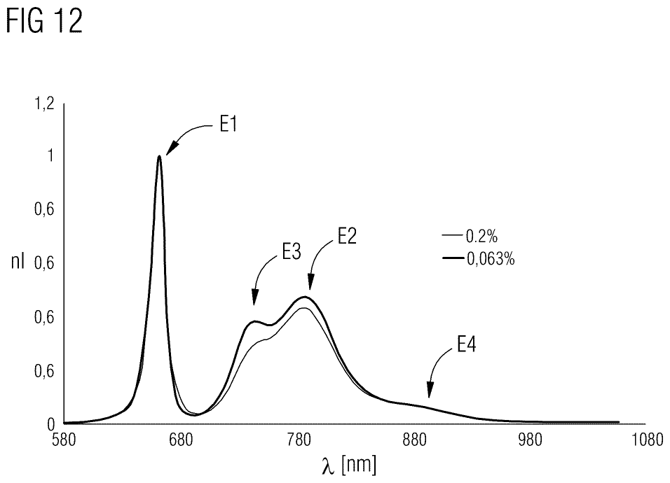

The exemplary embodiment shown in FIG. 12 shows two emission spectra with a first emission maximum E1, a second emission maximum E2, a third emission maximum E3 and a fourth emission maximum E4. The emission spectra were obtained with an optoelectronic component 1 comprising a conversion element 3 with a third rylene dye 43. In the conversion element 3, the concentration of the third rylene dye 43 varies. An optoelectronic component 1 comprises a concentration of the third rylene dye 43 of 0.2% by weight and another optoelectronic component 1 comprises a concentration of the third rylene dye 43 of 0.063% by weight. At the concentration of 0.2% by weight, a higher intensity is achieved.

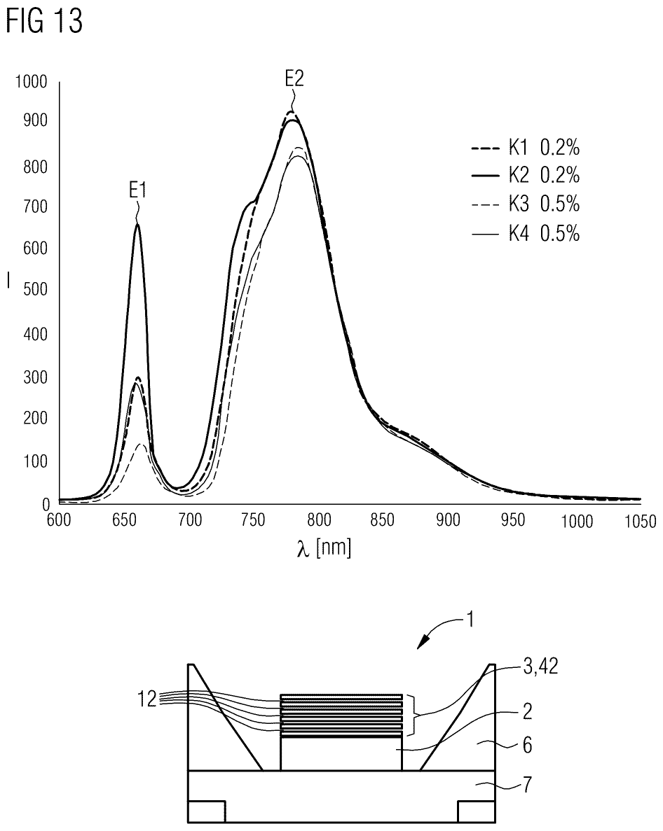

In the exemplary embodiment of FIG. 13, an optoelectronic component 1 with a plurality of conversion elements 3 is shown. The wavelength converting material 4 here is the second rylene dye 42.

Four emission spectra are shown in the figure. The optoelectronic component 1 of the first spectrum K1 comprises six conversion elements 3, wherein the concentration of wavelength converting material 4 in each conversion element 3 being 0.2% by weight. The optoelectronic component 1 of the second spectrum K2 comprises three conversion elements 3 and the concentration of wavelength converting materials 4 in each conversion element 3 is 0.2% by weight. The third spectrum K3 also shows the emission of an optoelectronic component 1 with three conversion elements 3, each with a concentration of 0.5% by weight of wavelength converting materials 4. The fourth spectrum K4 is obtained with an optoelectronic component 1 with two conversion elements 3, each with a concentration of 0.5% by weight of wavelength converting material 4.

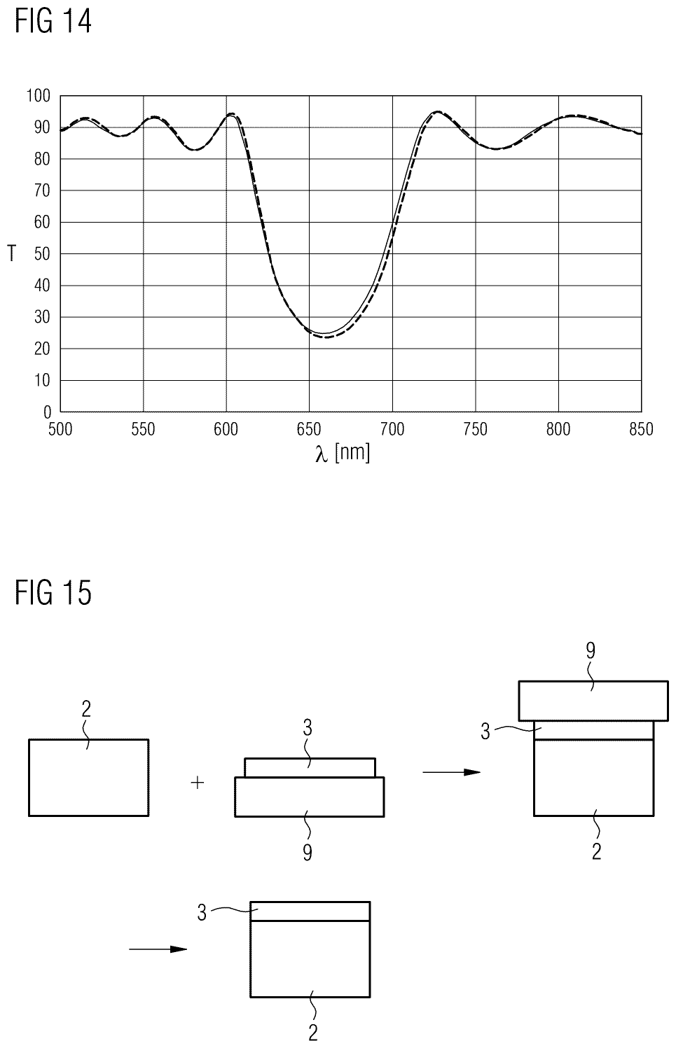

FIG. 14 shows the transmission spectrum of a dichroic mirror 8. Here, the transmission T is plotted against the wavelength λ. It can be seen that the transmission T is low at a wavelength in the range from 600 nm to 700 nm. This means that in this range the primary electromagnetic radiation is not transmitted by the dichroic mirror 8, but reflected. The primary radiation is reflected by the dichroic mirror 8 until the primary radiation is converted into secondary radiation and has a wavelength range greater than 700 nm. As a result, only a low concentration of wavelength converting materials 4 is required in the conversion element 3.

FIG. 15 describes the method for producing an optoelectronic component 1 according to an exemplary embodiment. First, a substrate 9 is provided. The substrate 9 is in particular a transparent substrate 9. The conversion element 3 is applied on the substrate 9. If necessary, the conversion element 3 is applied to the substrate 9 several times. The conversion element 3 and the substrate 9 can be separated. The conversion element 3 is then arranged on the semiconductor chip 2 so that the conversion element 3 is located between the substrate 9 and the semiconductor chip 2. Optionally, the substrate 9 can be detached.

The features and exemplary embodiments described in connection with the figures can be combined with one another in accordance with further exemplary embodiments, even if not all combinations are explicitly described. Furthermore, the embodiments described in connection with the figures may alternatively or additionally have further features as described in the general part.

The present disclosure is not limited to the description based on the exemplary embodiments. Rather, the present disclosure includes any new feature as well as any combination of features, which includes in particular any combination of features in the patent claims, even if this feature or combination itself is not explicitly stated in the patent claims or exemplary embodiments.

### LIST OF REFERENCE SYMBOLS

1 optoelectronic component
2 semiconductor chip
3 conversion element
31 first conversion element
32 second conversion element
4 wavelength converting material
41 first rylene dye
42 second rylene dye
43 third rylene dye
5 surrounding
6 housing
7 carrier
8 dichroic mirror
9 substrate
10 decoupling structure
12 adhesion promoter layer
N normalized intensity
I intensity
T transmission
E1 first emission maximum
E2 second emission maximum
E3 third maximum emission
E4 fourth emission maximum
K1 first spectrum
K2 second spectrum
K3 third spectrum
K4 fourth spectrum

What is claimed is:

1. An Ooptoelectronic component withcomprising:
a semiconductor chip which emits electromagnetic primary radiation of a first wavelength range during operation, and
at least one conversion element, wherein
the conversion element is arranged to emit electromagnetic secondary radiation of a second wavelength range, and
the electromagnetic secondary radiation is in the infrared spectral range, and wherein
the conversion element comprises at least a wavelength converting material and a matrix material, and
the wavelength converting material is a rylene dye and is selected from one of the following structural formulae: 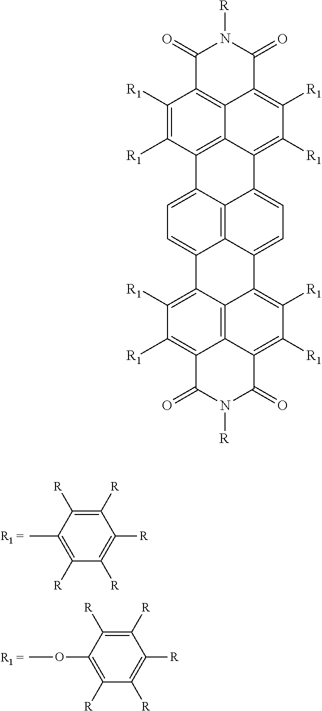
wherein each R is independently selected from the group consisting of H atoms, halide atoms, D atoms, substituted and unsubstituted alkyl groups, NO₂ groups, substituted and unsubstituted NH₂ groups, substituted and unsubstituted alkenyl groups, substituted and unsubstituted aromatics, substituted and unsubstituted heteroaromatics, nitrile groups, CO₂R-groups and CONR₂-groups, wherein R₂ is selected from H and alkyl groups and
where R₁ is selected from the structural formulae shown and from the group of H atoms, halide atoms and D atoms.

2. The optoelectronic component according to claim 1,
wherein at least one H atom of the rylene dye is exchanged with an atom with a higher mass than hydrogen.

3. The optoelectronic component according to claim 1,
wherein at least one or all of the wavelength converting materials in the conversion element comprises a concentration in a range between 0.01 wt % inclusive and 1.0 wt % inclusive.

4. The optoelectronic component according to claim 1,
wherein the matrix material is selected from epoxides, silicones, fluorosilicones, polymethyl methacrylates, polysiloxanes, polycarbonates, melting gels, glass or combinations thereof.

5. The optoelectronic component according to claim 1,
wherein a dichroic mirror is arranged on the side of the conversion element facing away from the semiconductor chip.

6. The optoelectronic component according to claim 1,
wherein in which the semiconductor chip and the conversion element are overmolded by an encapsulation.

7. The optoelectronic component according to claim 6,
wherein the encapsulation comprises a metal oxide or a metal nitride.

8. The optoelectronic component according to any one of claim 1,
wherein the primary radiation is in a wavelength range between 550 nm inclusive and 1000 nm inclusive.

9. The optoelectronic component according to claim 1,
wherein at least 50% of the emitted secondary radiation is in a wavelength range between 700 nm inclusive and 1000 nm inclusive.

10. The optoelectronic component according to claim 1,
wherein an inorganic phosphor is embedded in the matrix material.

11. The optoelectronic component according to claim 1,
wherein a quantum dot and/or a nanoparticle is embedded in the matrix material.

12. The optoelectronic component according to claim 1,
wherein the surface of the conversion element comprises an outcoupling structure.

13. The optoelectronic component according to any of claim 1,
wherein at least two conversion elements are arranged downstream of the semiconductor chip, and
wherein
a first conversion element of the at least two conversion elements, which is arranged closer to the semiconductor chip, comprises a first rylene dye whose secondary radiation is in the longer wavelength range than the secondary radiation of a second rylene dye in a second conversion element of the at least two conversion elements, which is further away from the semiconductor chip.

14. The optoelectronic component according to any claim 1, wherein the rylene dye is selected from:

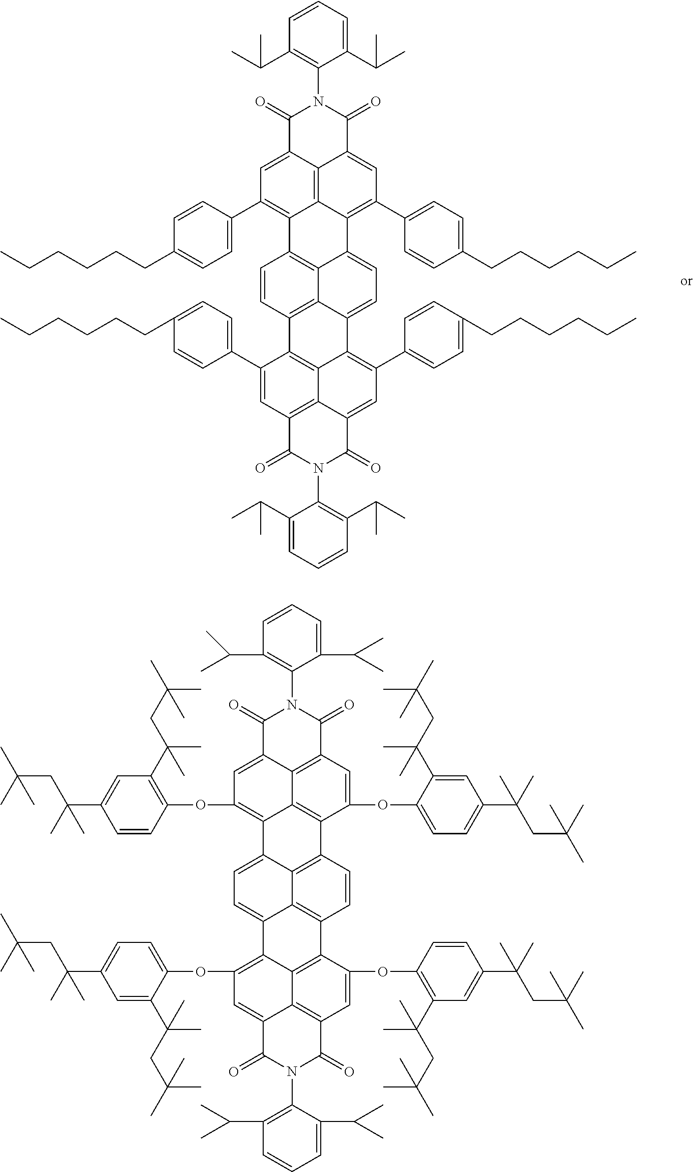

15. The optoelectronic component according to claim 1, wherein the semiconductor chip is a micro LED chip.

16. A method for producing an optoelectronic component comprising:
providing a semiconductor chip which is set up to emit primary radiation of a first wavelength range during operation,
producing a conversion element according to claim 1, which is up configured to emit secondary radiation of a second wavelength range, and
applying of the conversion element to the semiconductor chip, wherein
the electromagnetic secondary radiation is in the infrared spectral range.

17. The method for producing an optoelectronic component according to claim 16, wherein the conversion element is applied to a substrate (9) before being applied to the semiconductor chip and the conversion element and the substrate (9) are separated.

18. (canceled)

19. An optoelectronic component comprising:
a semiconductor chip which emits electromagnetic primary radiation of a first wavelength range during operation, and
at least one conversion element, wherein the conversion element is arranged to emit electromagnetic secondary radiation of a second wavelength range, and the electromagnetic secondary radiation is in the infrared spectral range, and
wherein the conversion element comprises at least a wavelength converting material and a matrix material, and
wherein the wavelength converting material is a rylene dye and is selected from one of the following structural formulae: 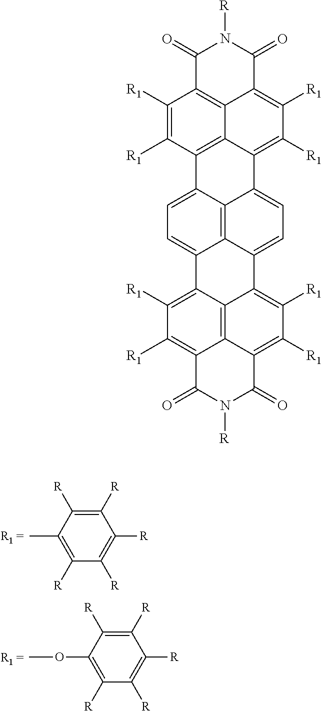
wherein each R is independently selected from the group consisting of H atoms, halide atoms, D atoms, substituted and unsubstituted alkyl groups, NO₂ groups, substituted and unsubstituted NH₂ groups, substituted and unsubstituted alkenyl groups, substituted and unsubstituted aromatics, substituted and unsubstituted heteroaromatics, nitrile groups, CO₂R-groups and CONR₂-groups, wherein R₂ is selected from H and alkyl groups,
where R₁ is selected from the structural formulae shown and from the group of H atoms, halide atoms and D atoms, and
wherein the primary radiation is in a wavelength range between 550 nm inclusive and 1000 nm inclusive.
